(19) United States
(12) Patent Application Publication
(10) Pub. No.: US 2017/0241005 A1
(43) Pub. Date: Aug. 24, 2017

(54) HEAT TREATMENT PROCESS FOR COMPONENTS COMPOSED OF NICKEL-BASED SUPERALLOYS

(71) Applicant: MTU Aero Engines AG, Munich (DE)

(72) Inventors: Thomas GOEHLER, Dachau (DE); Mlodszy Inzynier Roman SOWA, Gniewczyna (PL); Ralf RETTIG, Erlangen (DE); Nils RITTER, Erlangen (DE); Robert F. SINGER, Erlangen (DE)

(21) Appl. No.: 15/435,501

(22) Filed: Feb. 17, 2017

(30) Foreign Application Priority Data
Feb. 24, 2016 (DE) 102016202837.5

(51) Int. Cl. C22F 1/10; C23C 14/58; C23C 14/16; C22C 19/05

(52) U.S. Cl. CPC C22F 1/10; C22C 19/057; C23C 14/5806; C23C 14/16

(57) ABSTRACT

Disclosed is process for producing a component of a nickel-based superalloy in which a semifinished part of the component is subjected to a solution heat treatment at a temperature from 1300° C. to 1350° C. and a precipitation heat treatment at a temperature range from 900° C. to 1150° C. The solution heat treatment and/or the precipitation heat treatment are carried out together with further processing of the semifinished part. Also disclosed is a process for treating a component of a nickel-based superalloy after use for some hundreds of hours at a use temperature of more than 500° C. by carrying out a reconditioning heat treatment in the temperature range from 1100° C. to 1280° C.

### CROSS-REFERENCE TO RELATED APPLICATIONS

The present application claims priority wider 35 U.S.C. §119 of German Patent Application No. 102016202837.5, tiled Feb. 24, 2016, the entire disclosure of which is expressly incorporated by reference herein.

### BACKGROUND OF THE INVENTION

1. Field of the Invention

The invention relates to heat treatment processes for nickel-based superalloys for the production and treatment of components, preferably components of turbomachines such as aircraft engines or stationary gas turbines.

For the purposes of the present invention, a nickel-based alloy is a material having nickel as main component. A particular embodiment of nickel-based alloys is nickel-based superalloys, which for the present purposes are alloys which, due to their particular composition and microstructure, can be used at high temperatures up to close to their melting point.

2. Discussion of Background Information

Nickel-based superalloys are used in high-temperature applications, e.g. in the construction of stationary gas turbines or aircraft engines, because of their high-temperature strength. Here, a high-temperature application is an application in which the use temperature of a component produced from the alloy is in a temperature range above half the melting point of the alloy.

The good high-temperature properties and especially the excellent high-temperature strength of the nickel-based superalloys are due to a specific microstructure which is characterized by a γ matrix and γ′ precipitates embedded therein. The face-centered cubic γ phase of the matrix consists of the main constituent nickel and also elements such as cobalt, chromium, molybdenum, rhenium and tungsten which have been alloyed into nickel-based superalloys. Such alloy constituents, e.g. tungsten, rhenium and molybdenum, result in mixed crystal strengthening of the γ matrix, which gives the alloy strength in addition to the precipitation hardening due to the γ precipitates.

The alloy constituents rhenium, tungsten and molybdenum result not only in the mixed crystal strengthening of the γ matrix but additionally in stabilization of the γ′ precipitates and counter coarsening thereof, which would lead to a decrease in the creep strength.

However, the addition of refractory metals such as rhenium, tungsten and molybdenum to the alloy is associated with the problem that TCP phases (TCP=topologically close packed) are formed; these are brittle and can lead to crack formation.

The γ′ precipitate phases usually likewise have a face-centered cubic structure having the composition Ni₃(Al,Ti,Ta,Nb).

In addition, the strength of nickel-based superalloys can be increased by the formation of carbides which stabilize grain boundaries and thus contribute to creep strength.

The microstructure formation and stability is therefore of critical importance for the property profile of nickel-based superalloys in high-temperature applications.

It is already known that, in the case of appropriate nickel-based superalloys after casting of a semifinished part, or in the case of components configured as a single crystal after production of the single-crystal semifinished part, the corresponding semifinished parts can be subjected to a heat treatment which usually comprises a solution heat treatment and a precipitation heat treatment for precipitation of the γ′ precipitate phases.

In the case of a nickel-based superalloy of the latest generation, e.g. the alloy TMS-238 (alloy designation of the National Institute for Materials Science, Japan), a solution heat treatment at a plurality of hold temperatures in the range from 1230° C. to 1340° C. and a two-stage precipitation heat treatment in the temperature range from 1000° C. to 1150° C. and at 870° C., for example, have been proposed (see U.S. Pat. No. 8,771,440 and CA 02 508 688 A1, the entire disclosures of which are incorporated by reference herein). In the case of the solution heat treatment, a heat treatment at a hold temperature of 1300° Celsius for one hour and at a hold temperature of 1340° Celsius for five hours or more has correspondingly been proposed, while the precipitation heat treatment is carried out in a first stage at a temperature of from 1000° C. to 1150° C. for four hours, while the second stage of the precipitation heat treatment takes place at a hold time of 20 hours at 870° C.

This makes it clear that the production of such a component from a nickel-based superalloy is very complicated and that it is accordingly of interest to reduce this complication. In. addition, it should be ensured that components which have been produced in such a complicated way have a very long life, which under some circumstances can be prevented by formation of the TCP phases during use at high temperatures.

In view of the foregoing it would be advantageous to have available a process for producing a component composed of a nickel-based superalloy, in which the production of the component can be kept as uncomplicated as possible but at the same time the desired properties of the component can be set. In addition, it would be advantageous to be able to make a long life of such a component possible.

### SUMMARY OF THE INVENTION

The present invention provides process for producing a component of a nickel-based superalloy, in particular a component of a turbomachine. The process comprises subjecting a semifinished part of the component to a solution heat treatment at a temperature of from about 1300° C. to about 1375° C. and a precipitation heat treatment at a temperature of from about 900° C. to about 1150° C. The solution heat treatment and/or the precipitation heat treatment are carried out together with further processing of the semifinished part.

In one aspect of the process, the solution heat treatment may be carried out at least partly simultaneously with hot isostatic pressing of the semifinished part and/or the precipitation heat treatment may be carried out at least partly simultaneously with coating of the semifinished part. For example, the coating operation during the precipitation heat treatment may be carried out by chemical or physical vapor deposition or by spraying, e g., by hot gas spraying, or low-pressure plasma spraying.

In another aspect of the process, Al-containing layers, e.g., AlCr and/or PtAl layers, may be deposited at least partly during the precipitation heat treatment.

In yet another aspect of the process, the solution heat treatment may be carried out at one or more hold temperatures, where the one or last hold temperature may range from about 1310° C. to about 1375° C., e.g., from about 1340° C. to about 1350° C., and may be maintained for up to about 15 hours, e.g., up to about 10 hours, such as up to about 5 hours.

In a still further aspect, the solution heat treatment may be ended with cooling at a cooling rate of about 200 K/min or more, e.g., about 400 K/min or more.

In another aspect of the process, the precipitation heat treatment may be carried out in a single stage and/or may be carried out for about five or more hours, e.g., for about ten or more hours, such as from about 10 to about 25 hours, e.g., at a temperature of from about 1000° C. to about 1100° C.

In yet another aspect, an alloy having a composition comprising, in percent by weight,

from about 3.7% to about 7.0%, e.g., from about 5.0% to about 7.0%, such as from about 5.5% to about 6.0%, of Al

from about 6% to about 20%, e.g., from about 6% to about 8% or from about 10% to about 15.0%, such as from about 10.0% to about 12.0%, of Co

from about 2.1% to about 7.2%, e.g., from about 4.0% to about 6.0%, such as from about 4.5% to about 5.5%, of Cr

from about 1.0% to about 3.0%, e.g., from about 1.1% to about 2.5%, such as from about 1.1% to about 2.0%, of Mo

from about 5.0% to about 9.2%, e.g., from about 5.5% to about 7.0%, such as from about 5.7% to about 6.5%, of Re

from about 3.0% to about 8.5%, e.g., from about 3.1% to about 5.5%, such as from about 3.3% to about 5.0%, of Ru

from about 4.1% to about 11.9%, e.g., from about 5.0% to about 9.0%, such as from about 5.5% to about 8.0%, of Ta

from 0% to about 3.3%, e.g., from 0% to about 2.0%, such as from 0% to about 1.7%, of Ti

from about 2.1% to about 4.9%. e.g., from about 3.0% to about 4.5%, such as from about 3.5% to about 4.5%, of W

from 0% to about 0.05% of C

from 0% to about 0.1% of Si

from 0% to about 0.05% of Mn

from 0% to about 0.015% of P

from 0% to about 0.001% of S

from 0% to about 0.003% of B

from 0% to about 0.05% of Cu

from 0% to about 0.15% of Fe

from 0% to about 0.5%, e.g., from 0% to about 0.15%, of Hf

from 0% to about 0.015% of Zr

from 0% to about 0.001% of Y

and nickel and unavoidable impurities as balance,

may be used as nickel-based superalloy.

The present invention also provides a process for conditioning a component of a nickel-based superalloy, in particular a component of a turbomachine, e.g., produced by a process as set forth above, after use for some hundreds of hours at a use temperature of more than about 500° C. The process comprises carrying out a reconditioning heat treatment at a temperature of from about 1080° C. to about 1280° C.

In one aspect of the process, the reconditioning heat treatment may be carried out at a temperature of from about 1125° C. to about 1275° C., e.g., from about 1150° C. to about 1200° C. and/or for a time of more than about 10 hours, e.g., more than about 20 hours, such as more than about 25 hours.

In another aspect of the process, a precipitation heat treatment at a temperature of from about 900° C. to about 1150° C. together with or without a coating operation may be carried out subsequent to the reconditioning heat treatment.

In yet another aspect of the process, Al-containing layers, e.g., AlCr and/or PtAl layers, may be deposited at least partly during the precipitation heat treatment and/or the coating operation during the precipitation heat treatment may be carried out by chemical or physical vapor deposition or by spraying, e.g., by hot gas spraying, or low-pressure plasma spraying.

In a still further aspect of the process, the precipitation heat treatment may be carried out in a single stage and/or may be carried out for about five or more hours, e.g., for about ten or more hours, such as from about 10 to about 25 hours, e.g., in a temperature range of from about 1000° C. to about 1100° C.

In another aspect of the process, prior to the reconditioning heat treatment a stress-relieving heat treatment may be carried out at a temperature of from about 850° C. to about 1100° C. for about one to about five hours, e.g., from about two to about four hours.

In yet another aspect, an alloy having a composition comprising, in percent by weight,

from about 3.7% to about 7.0%, e.g., from about 5.0% to about 7.0%, such as from about 5.5% to about 6.0%, of Al

from about 6% to about 20%, e.g., from about 6% to about 8% or from about 10% to about 15.0%, such as from about 10.0% to about 12.0%, of Co

from about 2.1% to about 7.2%, e.g., from about 4.0% to about 6.0%, such as from about 4.5% to about 5.5%, of Cr

from about 1.0% to about 3.0%, e.g., from about 1.1% to about 2.5%, such as from about 1.1% to about 2.0%, of Mo

from about 5.0% to about 9.2%, e.g., from about 5.5% to about 7.0%, such as from about 5.7% to about 6.5%, of Re

from about 3.0% to about 8.5%, e.g., from about 3.1% to about 5.5%, such as from about 3.3% to about 5.0%, of Ru

from about 4.1% to about 11.9%, e.g., from about 5.0% to about 9.0%, such as from about 5.5% to about 8.0%, of Ta

from 0% to about 3.3%, e.g., from 0% to about 2.0%, such as from 0% to about 1.7%, of Ti

from about 2.1% to about 4.9%, e.g., from about 3.0% to about 4.5%, such as from about 3.5% to about 4.5%, of W

from 0% to about 0.05% of C

from 0% to about 0.1% of Si

from 0% to about 0.05% of Mn

from 0% to about 0.015% of P

from 0% to about 0.001% of S

from 0% to about 0.003% of B

from 0% to about 0.05% of Cu

from 0% to about 0.15% of Fe

from 0% to about 0.5%, e.g., from 0% to about 0.15%, of Hf

from 0% to about 0.015% of Zr

from 0% to about 0.001% of Y

and nickel and unavoidable impurities as balance,

may be used as nickel-based superalloy.

As set forth above, the invention proposes, according to a first aspect thereof, carrying out the required heat treatment with solution heat treatment and/or precipitation heat treatment in each case together with further processing steps to process a corresponding semifinished part composed of a nickel-based superalloy. Processing times and complication in the production of corresponding components can be significantly reduced in this way.

For example it can be advantageous in the case of cast semifinished parts to subject the semifinished part to processing by hot isostatic pressing (HIP) in order to eliminate pores and to achieve a further improvement in the mechanical properties. According to the invention, this can be carried out at least partly simultaneously with the solution heat treatment.

In addition, components of this type for high-temperature applications, for example in aircraft engines or stationary gas turbines, are provided with a protective coating, for example an oxidation protection layer, so that, according to the invention, a corresponding deposition of a layer can take place simultaneously with a precipitation heat treatment. Combining different processing steps enables time to be saved and the production of such components to be made less complicated.

For this purpose, a second stage of a precipitation heat treatment, as is provided in the prior art, can also be omitted. Accordingly, in the production of such a component composed of a nickel-based superalloy, the semifinished part can, after production of the semifinished part by casting, direct solidification or single-crystal drawing, be subjected to a solution heat treatment which can be carried out with various hold temperatures. After quenching of the component with rapid cooling to room temperature or close to room temperature, a single-stage precipitation heat treatment can follow; here, single-stage means that only one hold temperature is set over a relatively long period of time, for example more than five or ten minutes. It has been shown that the second stage of precipitation heat treatment described in the prior art, which is carried out at a lower temperature than in the first stage, in particular at a temperature of about 870° C., no longer has any significant influence on the formation of the γ′ precipitate phases and in particular on the diameter thereof, so that this processing step can be saved.

Instead, a single-stage precipitation heat treatment can be carried out in the temperature range from about 900° C. to about 1150° C., e.g., from about 1000° C. to about 1100° C., for a time of about five or more hours, e.g., for about ten or more hours, such as from about 10 to about 25 hours, with the overall complication being able to be kept low by combination with a coating process.

The coating which can be deposited during the precipitation heat treatment can have one or more Al-containing layers, in particular AlCr and/or PtAl layers or pure Al layers.

As coating process, it is possible to employ various methods in which the appropriate temperatures for the precipitation heat treatment can be applied, at least in a substep, to the semifinished part, for example chemical and/or physical vapor deposition (CVD chemical vapor deposition or PVD physical vapor deposition) or spraying processes, for example hot gas spraying, high-velocity flame spraying or low-pressure plasma spraying, or thermochemical diffusion treatments such as chromating or aluminizing. The coating can also be produced by vaporization (e.g. laser beam vaporization or electron beam vaporization) or cathode atomization (sputtering) or electrochemical deposition of constituents of the layer, for example platinum, additional deposition of other constituents such as aluminum by identical or similar processes, and finishing of the layer by allowing diffusion processes during a heat treatment which is simultaneously the precipitation heat treatment.

The solution heat treatment can, as mentioned above, be carried out at a plurality of hold temperatures, in particular in the temperature range from about 1300° C. to about 1375° C., with the last hold temperature being able to be in the temperature range from about 1310° C. to about 1375° C., e.g., from about 1340° C. to about 1350° C., and being able to be held for a time of up to about 15 hours, e.g., up to about ten hours, such as up to about five hours. The solution heat treatment can be completed by cooling at a cooling rate of about 200 K/min or more, e.g., about 400 K/min or more.

According to a further aspect of the present invention, for which protection is sought independently and in combination with other aspects of the invention, the invention proposes a process for conditioning a component composed of a nickel-based superalloy, in which a reconditioning heat treatment in a temperature range from about 1080° C. to 1280° C. is carried out on a component after use for a number of hundreds of hours, for example about 200 hours or more, e.g., about 1000 hours or more, at a use temperature of more than about 500° C., e.g. more than about 750° C. or in the range from about 900° C. to about 1100° C., in order to redissolve TCP phases which have possibly been formed.

The reconditioning heat treatment can, in particular, be carried out at a temperature of from about 1125° C. to about 1275° C., e.g., in the temperature range from about 1150° C. to about 1200° C. The duration of the reconditioning heat treatment can be more than about 10 hours, e.g., more than about 20 hours, such as more than about 25 hours, in order to ensure reliable dissolution of all TCP phases. The dissolution of the TCP phases further improves the mechanical strength of the component after prolonged use at relatively high temperatures and corresponding components can be used for a longer period of time.

Before the reconditioning heat treatment, a stress-relieving heat treatment of the component to be treated can be carried out at a temperature of from about 850° C. to about 1100° C. for a time of from about one to about five hours, e.g., from about two to about four hours, in order to dissipate residual stresses built up in the component.

The reconditioning heat treatment can be followed by an additional precipitation heat treatment in combination with or without a coating step, as has been described above in connection with the production process.

The above-described processes can be used, in particular, in the case of nickel-based superalloys of the latest generation, for example the alloy TMS-238 or alloys having the following composition in percent by weight:

from about 3.7% to about 7.0%, e.g., from about 5.0% to about 7.0%, such as from about 5.5% to about 6.0%, of Al

from about 6% to about 20%, e.g., from about 6% to about 8% or from about 10% to about 15.0%, such as from about 10.0% to about 12.0%, of Co

from about 2.1% to about 7.2%, e.g., from about 4.0% to about 6.0%, such as from about 4,5% to about 5.5%, of Cr

from about 1.0% to about 3.0%, e.g., from about 1.1% to about 2.5%, such as from about 1.1% to about 2.0%, of Mo

from about 5.0% to about 9.2%, e.g., from about 5.5% to about 7.0%, such as from about 5.7% to about 6.5%, of Re

from about 3.0% to about 8.5%, e.g., from about 3.1% to about 5.5%, such as from about 3.3% to about 5.0%, of Ru

from about 4.1% to about 11.9%, e.g., from about 5.0% to about 9.0%, such as from about 5.5% to about 8.0%, of Ta

from 0% to about 3.3%, e.g., from 0% to about 2.0%, such as from 0% to about 1.7%, of Ti

from about 2.1% to about 4.9%. e.g., from about 3.0% to about 4.5%, such as from about 3.5% to about 4.5%, of W

from 0% to about 0.05% of C

from 0% to about 0.1% of Si

from 0% to about 0.05% of Mn

from 0% to about 0.015% of P

from 0% to about 0.001% of S

from 0% to about 0.003% of B

from 0% to about 0.05% of Cu

from 0% to about 0.15% of Fe

from 0% to about 0.5%, e.g., from 0% to about 0.15%, of Hf

from 0% to about 0.015% of Zr

from 0% to about 0.001% of Y

and nickel and unavoidable impurities as balance.

### DETAILED DESCRIPTION OF EMBODIMENT OF THE INVENTION

The particulars shown herein are by way of example and for purposes of illustrative discussion of the embodiments of the present invention only and are presented in the cause of providing what is believed to be the most useful and readily understood description of the principles and conceptual aspects of the present invention. In this regard, no attempt is made to show details of the present invention in more detail than is necessary for the fundamental understanding of the present invention, the description making apparent to those of skill in the art how the several forms of the present invention may be embodied in practice.

A rotor blade or guide blade of a low-pressure turbine of an aircraft engine is cast from a nickel-based superalloy TMS-238 and subsequently heated in an HIP furnace, i.e. a heating apparatus which simultaneously allows hot isostatic pressing, to a temperature of 1300° C., then held for ten minutes, subsequently heated to 1310° C. and held there for one hour. Heating to 1335° C. is then carried out and this temperature is held for three hours. To conclude the solution heat treatment, the semifinished part is hot isostatically pressed at 1345° C. for 20 hours and subsequently cooled at a cooling rate of 400 K/min to a temperature below 400° C., preferably room temperature.

After removal from the HIP furnace, the semifinished part is provided with an AlCr coating by vapor deposition of aluminum and chromium in a coating apparatus, for example a PVD coating chamber, with a diffusion heat treatment, which is at the same time also a precipitation heat treatment, being carried out at a temperature in the range from 1000° C. to 1100° C., for example 1050° C., for from 8 to 24 hours, e.g. 20 hours, in order to finish the coating. After cooling to room temperature, the heat treatment with the solution heat treatment and the precipitation heat treatment is concluded and the component according to the invention is finished. The corresponding rotor blade or guide blade can then be used in a low-pressure turbine of an aircraft engine for several hundred or thousand hours.

To ensure that no brittle TCP phases are present in the rotor blade or guide blade after operation of the low-pressure turbine over a prolonged period of more than 100 hours, the guide blade or rotor blade concerned is subjected to a reconditioning heat treatment which is carried out at a temperature in the range from 1100° C. to 1200° C., for example 1150° C., for from 10 to 40 hours, e.g. 30 hours, during overhauling of the low-pressure turbine. Since possible TCP phases dissolve at this temperature of the reconditioning heat treatment, it is ensured that there are no longer any brittle phases in the component after a heat treatment but instead that the component can be used again reliably. At the same time, the heat treatment below the temperature for dissolution of the γ′ precipitate phases ensures that the strength of the component is not impaired.

Although the present invention has been described in detail with the aid of the working examples, the invention is not restricted to these working examples but instead modifications in which individual features can be altered within the indicated scope of protection of the accompanying claims are possible. The disclosure encompasses all combinations of the individual features presented.

What is claimed is:

1. A process for producing a component of a nickel-based superalloy, wherein the process comprises subjecting a semifinished part of the component to a solution heat treatment at a temperature of from about 1300° C. to about 1375° C. and a precipitation heat treatment at a temperature of from about 900° C. to about 1150° C., the solution heat treatment and/or the precipitation heat treatment being carried out together with further processing of the semifinished part.

2. The process of claim 1, wherein the solution heat treatment is carried out at least partly simultaneously with hot isostatic pressing of the semifinished part.

3. The process of claim 1, wherein the precipitation heat treatment is carried out at least partly simultaneously with coating of the semifinished part.

4. The process of claim 3, wherein Al-containing layers are deposited at least partly during the precipitation heat treatment.

5. The process of claim 3, wherein the coating operation during the precipitation heat treatment is carried out by chemical or physical vapor deposition or by spraying.

6. The process of claim 1, wherein the solution heat treatment is carried out at one or more hold temperatures, where the one or last hold temperature ranges from about 1310° C. to about 1375° C. and is maintained for up to about 15 hours.

7. The process of claim 1, wherein the solution heat treatment is ended with cooling at a cooling rate of at least about 200 K/min.

8. The process of claim 1, wherein the precipitation heat treatment is carried out in a single stage.

9. The process of claim 1, wherein the precipitation heat treatment is carried out for at least about five hours.

10. The process of claim 9, wherein the precipitation heat treatment is carried out at a temperature from about 1000° C. to about 1100° C.

11. The process of claim 1, wherein an alloy having a composition comprising, in percent by weight,
from about 3.7% to about 7.0% of Al
from about 6% to about 20% of Co
from about 2.1% to about 7.2% of Cr
from about 1.0% to about 3.0% of Mo
from about 5.0% to about 9.2% of Re
from about 3.0% to about 8.5% of Ru
from about 4.1% to about 11.9% of Ta
from 0% to about 3.3% of Ti
from about 2.1% to about 4.9% of W
from 0% to about 0.05% of C
from 0% to about 0.1% of Si
from 0% to about 0.05% of Mn
from 0% to about 0.015% of P
from 0% to about 0.001% of S
from 0% to about 0.003% of B
from 0% to about 0.05% of Cu
from 0% to about 0.15% of Fe
from 0% to about 0.5% of Hf
from 0% to about 0.015% of Zr
from 0% to about 0.001% of Y
and nickel and unavoidable impurities as balance,
is used as nickel-based superalloy.

12. A process for conditioning a component of a nickel-based superalloy after use for some hundreds of hours at a use temperature of more than about 500° C., wherein the process comprises carrying out a reconditioning heat treatment at a temperature of from about 1080° C. to about 1280° C.

13. The process of claim 12, wherein the reconditioning heat treatment is carried out at a temperature of from about 1125° C. to about 1275° C. and/or for at least about 10 hours.

14. The process of claim 12, wherein a precipitation heat treatment at a temperature of from about 900° C. to about 1150° C. together with or without a coating operation is carried out subsequent to the reconditioning heat treatment.

15. The process of claim 14, wherein Al-containing layers are deposited at least partly during the precipitation heat treatment and/or wherein the coating operation during the precipitation heat treatment is carried out by chemical or physical vapor deposition or by spraying.

16. The process of claim 14, wherein the precipitation heat treatment is carried out in a single stage.

17. The process of claim 14, wherein the precipitation heat treatment is carried out for at least about five hours.

18. The process of claim 17, wherein the precipitation heat treatment is carried out at a temperature of from about 1000° C. to about 1100° C.

19. The process of claim 14, wherein prior to the reconditioning heat treatment a stress-relieving heat treatment is carried out at a temperature of from about 850° C. to about 1100° C. for from about one to about five hours.

20. The process of claim 14, wherein an alloy having a composition comprising, in percent by weight,
from about 3.7% to about 7.0% of Al
from about 6% to about 20% of Co
from about 2.1% to about 7.2% of Cr
from about 1.0% to about 3.0% of Mo
from about 5.0% to about 9.2% of Re
from about 3.0% to about 8.5% of Ru
from about 4.1% to about 11.9% of Ta
from 0% to about 3.3% of Ti
from about 2.1% to about 4.9% of W
from 0% to about 0.05% of C
from 0% to about 0.1% of Si
from 0% to about 0.05% of Mn
from 0% to about 0.015% of P
from 0% to about 0.001% of S
from 0% to about 0.003% of B
from 0% to about 0.05% of Cu
from 0% to about 0.15% of Fe
from 0% to about 0.5% of Hf
from 0% to about 0.015% of Zr
from 0% to about 0.001% of Y
and nickel and unavoidable impurities as balance,
is used as nickel-based superalloy.
